(19) United States
(12) Patent Application Publication
(10) Pub. No.: US 2024/0032424 A1
(43) Pub. Date: Jan. 25, 2024

(54) METHOD FOR MANUFACTURING MEASURING DEVICE AND MEASURING DEVICE

(71) Applicant: Futaba Corporation, Mobara-shi (JP)

(72) Inventors: Yuji SASAKI, Mobara-shi (JP); Takehiro TAKEDA, Mobara-shi (JP)

(21) Appl. No.: 18/354,999

(22) Filed: Jul. 19, 2023

(30) Foreign Application Priority Data
Jul. 21, 2022 (JP) 2022-116408

(51) Int. Cl. H10N 10/01; H10N 10/17; H10N 10/80; G01K 7/02

(52) U.S. Cl. CPC H10N 10/01; H10N 10/17; H10N 10/80; G01K 7/02

(57) ABSTRACT

A method for manufacturing a measuring device includes: a step of preparing a structure; a step of fixing a piece to a housing by first welding on a distal end face of the structure; and a step of polishing a welded portion formed by the first welding and the distal end face. The structure includes: the housing having a first end and a second end which are open in one direction; a thermocouple extending in the one direction in the housing; and the piece provided in the housing, exposed from the first end, and configured to hold the thermocouple. The piece has a side face facing an inner surface of the housing. In the step of preparing the structure, the thermocouple is accommodated between a pair of grooves provided on the side face and the inner surface of the housing by inserting the piece into the housing.

### CROSS-REFERENCE TO RELATED APPLICATION

This application is based on Japanese Patent Application No. 2022-416408 filed with Japan Patent Office on Jul. 21, 2022 and claims the benefit of priority thereto. The entire contents of the Japanese patent application are incorporated herein by reference.

### TECHNICAL FIELD

The present disclosure relates to a method for manufacturing a measuring device and a measuring device.

### BACKGROUND

A manufacturing method of a measuring device for measuring the temperature of a mold wall for injection molding is known (see, for example, Japanese Patent No. 4177333). In this manufacturing method, a measuring element is inserted into a hole provided in a sensor body for each measuring element, and the measuring element and the front face of the sensor body are polished with the measuring element slightly protruding from the front face of the sensor body.

### SUMMARY

In the manufacturing method described in Japanese Patent No. 4177333, since the inside diameter of the hole provided in the sensor body is about the same as the outside diameter of the measuring element, the measuring element may not be easily inserted into the hole. There is a need in the technical field for easy manufacturing of measuring devices.

A method for manufacturing a measuring device according to one aspect of the present disclosure includes: a step of preparing a structure, the structure including: a housing having a cylindrical shape in which a first end and a second end in one direction are open; a thermocouple extending in the one direction in the housing; and a piece having a columnar shape, the piece provided in the housing, the piece exposed from the first end, the piece configured to hold the thermocouple; a step of fixing the piece to the housing by first welding on a distal end face of the structure, the distal end face including the first end; and a step of polishing a welded portion formed by the first welding and the distal end face. The piece has a side face facing an inner surface of the housing. A pair of grooves penetrating through the piece in the one direction are provided on the side face. In the step of preparing the structure, the thermocouple is accommodated between the pair of grooves and the inner surface of the housing by inserting the piece into the housing.

in the method for manufacturing a measuring device, the thermocouple is accommodated between the pair of grooves provided on the side face of the piece and the inner surface of the housing by inserting the piece into the housing. That is, two holes are formed by the inner surface of the housing and the grooves, and the thermocouple is already accommodated in the holes at the time when the holes are formed. Therefore, there is no need to pass the thermocouple through holes. As a result, manufacturing of the measuring device can be facilitated.

In the step of preparing the structure, the thermocouple may be accommodated between the pair of grooves and the inner surface of the housing by inserting the piece into the housing after inserting the thermocouple into the housing. In this case, the pair of grooves are aligned with the thermocouple in the width direction of the groove, and then the piece is inserted into the housing, whereby the thermocouple is fitted into the grooves along the grooves as the piece is inserted. Two holes are formed by the inner surface of the housing and the grooves, and the thermocouple is already accommodated in the holes at the time when the holes are formed. For example, in order to insert the thermocouple into holes having inner diameters equivalent to the outer diameter of the wire of the thermocouple, it is necessary to align the thermocouple with the holes in two axes. On the other hand, in the above-mentioned manufacturing method, the positioning in two axes (the width direction of the groove and the length direction of the groove) is individually performed. Therefore, compared with the case where the thermocouple is inserted into the holes provided in the housing, the manufacturing of the measuring device can be facilitated.

In the step of preparing the structure, the thermocouple may be accommodated between the pair of grooves and the inner surface of the housing by inserting the piece and the thermocouple into the housing so that a front face of the piece is exposed from the first end after fixing the thermocouple to the piece by auxiliary welding on the front face in a state in which the thermocouple is accommodated in the pair of grooves. In this case, the thermocouple is aligned with the pair of grooves in the width direction of the groove, and then the thermocouple can be aligned with the piece along the grooves. Therefore, since the positioning in the two axes (the width direction of the groove and the length direction of the groove) can be individually performed, the manufacturing of the measuring device can be facilitated as compared with the case where the thermocouple is inserted into the holes provided in the housing.

The first welding may be performed inside an outer edge of the first end. This makes it possible to prevent deformation such as sagging of the outer edge due to welding. As a result, the flatness of the polished distal end face can be improved.

The first welding may be performed along a boundary between the housing and the piece on the distal end face. In this case, since the boundary between the housing and the piece on the distal end face is welded without any gap, the bonding strength between the housing and the piece is improved. As a result, the withstand voltage performance of the measuring device is improved.

The method for manufacturing a measuring device may further include a step of fixing the piece to the housing by second welding on an outer peripheral surface of the housing. In this case, since the piece is fixed to the housing not only on the distal end face but also on the outer peripheral surface, the bonding strength between the housing and the piece is further improved. As a result, the withstand voltage performance of the measuring device is further improved.

A groove may be provided on the outer peripheral surface of the housing. The second welding may be performed in the groove. In this case, even if deformation such as bulging occurs in the housing due to the second welding, the deformation occurs in the groove. This makes it possible to reduce the possibility that the deformed portion protrudes from the outer peripheral surface. For example, when the measuring device is used by being inserted into a hole provided in a metal mold, it is possible to reduce the possibility of a problem that the measuring device cannot be inserted into the hole.

In the step of polishing the welded portion and the distal end face, the welded portion and the distal end face may be polished so that distal ends of the thermocouple are exposed. This process shortens the time required for heat to reach the pair of wires when the measuring device is used. This makes it possible to improve the response of the measuring device.

A measuring device according to another aspect of the present disclosure includes: a housing having a first end and a second end in one direction, the housing having a cylindrical shape in which the first end and the second end are open; a thermocouple extending in the one direction in the housing; and a piece having a columnar shape, provided in the housing, exposed from the first end and configured to hold the thermocouple. The piece has a side face facing an inner surface of the housing and a distal end face exposed from the first end. A pair of grooves penetrating through the piece in the one direction are provided on the side face. The thermocouple is accommodated in the pair of grooves and extends to the distal end face.

In the measuring device, the thermocouple is accommodated between the pair of grooves provided on the side face of the piece and the inner surface of the housing. Since the piece and the housing are separate members, the thermocouple can be accommodated in the pair of grooves by inserting the piece into the housing. That is, two holes are formed by the inner surface of the housing and the grooves, and the thermocouple is already accommodated in the holes at the time when the holes are formed. Therefore, there is no need to pass the thermocouple through holes. As a result, manufacturing of the measuring device can be facilitated.

According to the present disclosure, the manufacturing of the measuring device can be facilitated.

### BRIEF DESCRIPTION OF THE DRAWINGS

FIG. 1 is a cross-sectional view showing a configuration of a measuring device.

FIG. 2 is an enlarged cross-sectional view of the range P shown in FIG. 1.

FIG. 3 is a flowchart showing an example of a method for manufacturing a measuring device according to an embodiment.

FIG. 4A is a plan view for explaining the insertion step S11 shown in FIG. 3.

FIG. 4B is a cross-sectional view showing a cross section along the line A1-A1 in FIG. 4A.

FIG. 5A is a plan view for explaining the insertion step S12 shown in FIG. 3.

FIG. 5B is a cross-sectional vies showing a cross section along the line A2-A2 in FIG. 5A.

FIG. 6A is a plan view for explaining the fixing step S2 shown in FIG. 3.

FIG. 6B is a cross-sectional view showing a cross section along the line A3-A3 in FIG. 6A.

FIG. 7A is a plan view for explaining the fixing step S3 shown in FIG. 3.

FIG. 7B is a cross-sectional view showing a cross section along the line A4-A4 in FIG. 7A.

FIG. 8A is a plan view for explaining the polishing step S4 shown in FIG. 3.

FIG. 8B is a cross-sectional view showing a cross section along the line A5-A5 in FIG. 8A.

FIG. 9 is a flowchart showing an example of a method for manufacturing a measuring device according to another embodiment.

FIG. 10A is a plan view for explaining the insertion step S51 shown in FIG. 9.

FIG. 10B is a cross-sectional view showing a cross section along the line B1-B1 in FIG. 10A.

FIG. 11A is a plan view for explaining the fixing step S52 shown in FIG. 9.

FIG. 11B is a cross-sectional view showing a cross section along the line B2-B2 in FIG. 11A.

FIG. 12A is a plan view for explaining the insertion step S53 shown in FIG. 9.

FIG. 12B is a cross-sectional view showing a cross section along the line B3-B3 in FIG. 12A.

### DETAILED DESCRIPTION

Hereinafter, embodiments of the present disclosure will be described in detail with reference to the drawings. In the drawings, the same or corresponding elements are denoted by the same reference numerals, and redundant description will be omitted.

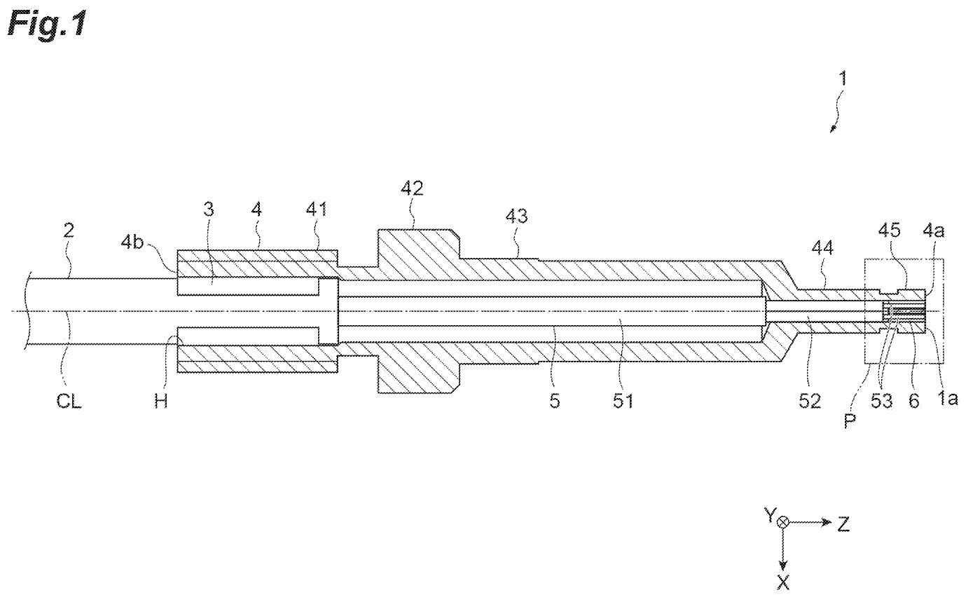

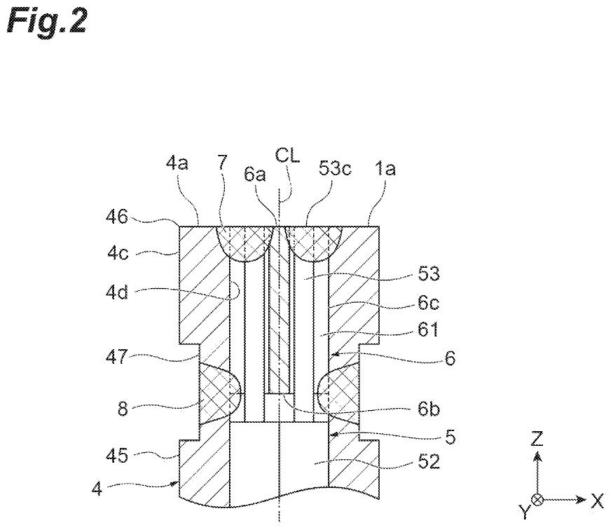

A measuring device manufactured by a method for manufacturing the measuring device according to an embodiment will he described with reference to FIGS. 1 and 2. FIG. 1 is a cross-sectional view showing a configuration of a measuring device. FIG. 2 is an enlarged cross-sectional view of the range P shown in FIG. 1. A measuring device I shown in FIG. 1 is a temperature sensor for measuring the temperature of a surface of a mold for injection molding. The measuring device 1 has a rod-like shape extending in the Z direction (one direction). The measuring device I is inserted into a hole provided in the mold along the central axis CL. A distal end face 1a of the measuring device 1 in the Z direction is in contact with the resin flowing into the mold to be measured. At this time, the distal end face 1a forms a part of the mold.

The measuring device 1 includes a tube 2, a swaging ring 3, a housing 4, a thermocouple 5, and a piece 6. The tube 2 is a tubular member made of, for example, a fluororesin. The tube 2 covers the thermocouple 5, The distal end portions of the thermocouple 5 are not covered with the tube 2 and protrude from the distal end portion of the tube 2. The swaging ring 3 is a cylindrical member having a notch extending from one end to the other end. In other words, the cross section of the swaging ring 3 orthogonal to the central axis CL has a C-shaped shape. The swaging ring 3 binds the thermocouple 5 from the outer peripheral surface of the tube 2 on the distal end portion of the tube 2.

The housing 4 is a cylindrical member having a first end 4a and a second end 4b open in the Z direction. The housing 4 has a circular cylindrical shape, for example. The housing 4 is made of stainless steel (for example, SUS630). A hole H penetrating through the housing 4 from the first end 4a to the second end 4b is provided in the housing 4. The housing 4 includes a base end portion 41, a flange 42, a cylindrical portion 43, a cylindrical portion 44, and a distal end portion 45. The base end portion 41, the flange 42, the cylindrical portion 43, the cylindrical portion 44 and the distal end portion 45 are arranged in this order from the second end 4b toward the first end 4a.

The base end portion 41 is a portion including the second end 4b. The distal end portion of the tube 2 is press-fitted together with the swaging ring 3 from the second end 4b into the base end portion 41. The flange 42 extends outward around the central axis CL over the entire circumference of the housing 4. The flange 42 is a portion for positioning the distal end face 1a. For example, when the measuring device 1 is inserted into the hole provided in the mold, the flange 42 abuts against a part of the mold, As a result, the position of the distal end face 1a is determined. The cylindrical portion 43, the cylindrical portion 44 and the distal end portion 45 accommodate the distal end portions of the thermocouple 5 which are not covered with the tube 2. The inner diameter of the cylindrical portion 43 is larger than the inner diameters of the cylindrical portion 44 and the distal end portion 45.

As shown in FIG. 2, the distal end portion 45 is a portion including the first end 4a. An outer edge 46 of the first end 4a is farthest away from the central axis CL at the first end 4a. The housing 4 has an outer peripheral surface 4c and an inner surface 4d. A groove 47 is provided on the outer peripheral surface 4c of the distal end portion 45. The groove 47 is a portion in which a part of the outer peripheral surface 4c is recessed toward the central axis CL, for example. The groove 47 is provided, for example, around the central axis CL over the entire circumference of the outer peripheral surface 4c. The groove 47 is provided, for example, at a position surrounding the outer periphery of a back face 6b described later.

The thermocouple 5 extends in the Z direction inside the housing 4. The thermocouple 5 measures a temperature difference based on a thermoelectric power at a contact point between two different kinds of metal wires (a pair of wires 53) and an object to be measured. Each of the pair of wires 53 is individually covered by a coating 52, and the pair of wires 53 covered by the coatings 52 are collectively covered by a coating 51. The distal end portions of the pair of wires 53 are not covered by either the coating 51 or the coating 52 (exposed from the coating 52). The portion of the thermocouple 5 covered by the coating 51 is accommodated in the cylindrical portion 43. The portion of the thermocouple 5 covered by the coating 52 is accommodated in the cylindrical portion 44. Hereinafter, the direction. in which the pair of wires 53 are arranged is referred to as the X direction. A direction orthogonal to the X direction and the Z direction is referred to as the Y direction.

The piece 6 is a columnar member for holding the thermocouple The piece 6 has a circular cylindrical shape, for example. The piece 6 is made of stainless steel (for example, SUS630). The piece 6 is provided in the housing 4 and is exposed from the first end 4a. More specifically, the piece 6 is accommodated in the distal end portion of the housing 4. The outer diameter of the piece 6 is about the same as the inner diameter of the housing 4 (distal end portion 45). The piece 6 has a front face 6a and a back face 6b which are both end faces in the Z direction, and a side face 6c. The front face 6a is exposed from the first end 4a. The side face 6c faces the inner surface 4d of the housing 4 (distal end portion 45).

A pair of grooves 61 penetrating through the piece 6 in the Z direction are provided on the side face 6c. Each groove 61 extends from the front face 6a to the back face 6b. In the present embodiment, the pair of grooves 61 are provided with respect to the central axis CL. Each groove 61 is recessed toward the central axis CL. The cross section of each groove 61 orthogonal to the central axis CL has a U-shaped shape, for example. The width and depth of each groove 61 are larger than the diameter of the wire 53. In each groove 61, the wire 53 (a portion not covered by the coating 52) of the thermocouple 5 is accommodated over the entire length of the groove 61, and a distal end 53c of the wire 53 is exposed on the distal end face 1a.

The measuring device 1 further includes a welded portion 7 and a welded portion 8. The welded portion 7 is provided on the distal end face 1a. In the present embodiment, the welded portion 7 is provided in a circular shape along the boundary line between the housing 4 and the piece 6 on the distal end face 1a. The housing 4 (distal end portion 45), the piece 6 and the thermocouple 5 are fixed to each other on the distal end face 1a by the welded portion 7. The welded portion 8 is provided in the groove 47. The welded portion 8 is provided over the entire circumference of the groove 47. The housing 4 and the piece 6 (the bottom portion of the piece 6) are fixed to each other by the welded portion 8.

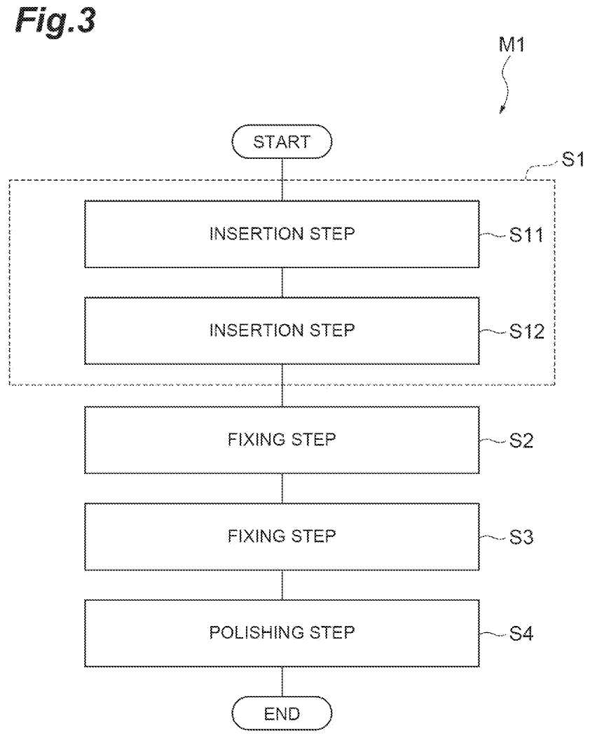

Next, a method for manufacturing the measuring device 1 according to an embodiment will be described with reference to FIG. 3. FIG. 3 is a flowchart showing an example of a method for manufacturing the measuring device 1 according to an embodiment. As shown in FIG. 3, a manufacturing method MI is a method for manufacturing the measuring device I and includes a preparation step S1, a fixing step S2, a fixing step S3, and a polishing step S4.

### Preparation Step S1

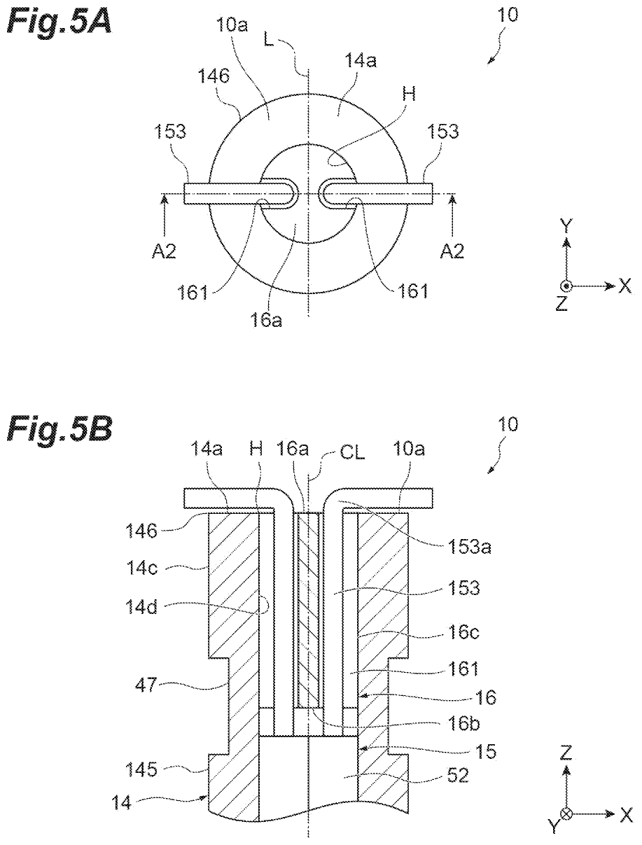

First, the preparation step S1 is performed. The preparation step S1 is a step of preparing a structure 10. The structure 10 includes a housing 14, a thermocouple 15, and a piece 16 (see FIG. 5B). The housing 14 is a member serving as a source of the housing 4 of the measuring device 1, and is mainly different from the housing 4 in that the housing 14 includes a distal end portion 145 instead of the distal end portion 45. The distal end portion 145 is a portion serving as a source of the distal end portion 45, and is mainly different from the distal end portion 45 in that the distal end portion 145 includes a first end 14a, an outer peripheral surface 14c and an inner surface 14d instead of the first end 4a, the outer peripheral surface 4c and the inner surface 4d. The first end 14a, the outer peripheral surface 14c and the inner surface 14d are portions serving as sources of the first end 4a, the outer peripheral surface 4c and the inner surface 4d, respectively. In other words, the housing 14 is a cylindrical member having the first end 14a and the second end 4b open in the Z direction. The above-described groove 47 is provided on the outer peripheral surface 14c.

The thermocouple 15 is a member serving as a source of the thermocouple 5 of the measuring device 1, and is mainly different from the thermocouple 5 in that the thermocouple 15 includes a pair of wires 153 instead of the pair of wires 53. The pair of wires 153 are members serving as sources of the pair of wires 53, and are mainly different from the pair of wires 53 in that each wire 153 further includes a distal end portion 153a. The distal end portion 153a is a portion including a distal end of the wire 153. The thermocouple 15 extends in the Z direction inside the housing 14.

The piece 16 is a member serving as a source of the piece 6 of the measuring device 1, and is mainly different from the piece 6 in that the piece 16 includes a front face 16a instead of the front face 6a. The front face 16a is a portion serving as a source of the front face 6a. The piece 16 is a columnar member for holding the thermocouple 15. Specifically, the piece 16 holds the pair of wires 153 so as to be separated from each other in the X direction. The piece 16 is provided in the housing 14 (distal end portion 145) and is exposed from the first end 14a. The piece 16 has a side face 16c facing the inner surface 14d of the housing 14. A pair of grooves 161 are provided on the side face 16c. Each of the pair of grooves 161 penetrates through the piece 16 in the Z direction. The wire 153 is held in each groove 161. The structure 10 has a distal end face 10a including the first end 14a.

In the preparation step S1, the thermocouple 15 is accommodated between the pair of grooves 161 and the inner surface 14d of the housing 14 by inserting the piece 16 into the housing 14. The preparation step S1 includes an insertion step S11 and an insertion step S12.

### Insertion Step S11

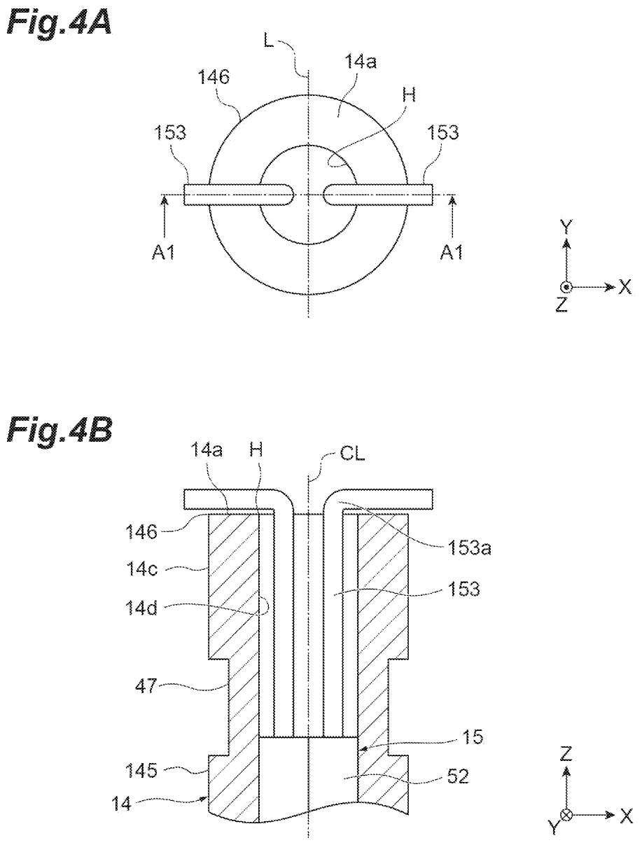

The insertion step S11 will be described in detail with reference to FIGS. 4A and 4B. FIG. 4A is a plan view for explaining the insertion step S11 shown in FIG. 3. FIG. 4B is a cross-sectional view showing a cross section along the line A1-A1 in FIG. 4A. As shown in FIGS. 4A and 4B, the insertion step S11 is a step of inserting the thermocouple 15 into the housing 14, in the insertion step S11, for example, the distal end portions of the thermocouple 15 are inserted into the housing 14 from the second end 4b. At this time, the thermocouple is inserted into the housing 14 so that each distal end portion 153a of the pair of wires 153 projects from the first end 14a to the outside of the housing 14.

Then, the pair of wires 153 are bent at a substantially right angle so that the distal end portions 153a of the pair of wires 153 are spaced apart from each other in the X direction. The distal end portion 153a of each wire 153 may be further away from the central axis CL than an outer edge 146 of the first end 14a. When the distal end portion 153a which is bent abuts against the first end 14a, each wire 153 is positioned in the Z direction. The pair of wires 153 are symmetrically arranged with respect to a virtual line L, The virtual line L is a virtual line crossing the central axis CL and extending in the Y direction.

### Insertion Step S12

Following the insertion step S11, the insertion step S12 is performed. The insertion step S12 will he described in detail with reference to FIGS. 5A and 5B. FIG. 5A is a plan view for explaining the insertion step S12 shown in FIG. 3. FIG. 5B is a cross-sectional view showing a cross section along the line A2-A2 in FIG. 5A. As shown in FIGS. 5A and 5B, the insertion step S12 is a step of inserting the piece 16 into the housing 14.

in the insertion step S12, for example, the distal end portions 153a of the pair of wires 153 are aligned and accommodated in the pair of grooves 161 on a back face 16b of the piece 16, respectively. In this state, the piece 16 is inserted into the housing 14 from the first end 14a of the housing 14. At this time, as the piece 16 is inserted, each wire 153 is fitted into the groove 161 along the groove 161. The piece 16 is inserted into the housing 14 until the front face 16a is flush with the first end 14a. As a result, the thermocouple 15 (the pair of wires 153) is accommodated between the pair of grooves 161 and the inner surface 14d of the housing 14, At this time, the front face 16a is exposed from the first end 14a.

As described above, in the preparation step S1, the thermocouple 15 is inserted into the housing 14 (insertion step S11). Thereafter, the piece 16 is inserted into the housing 14, so that the thermocouple 15 is accommodated between the pair of grooves 161 and the inner surface 14d of the housing 14 (insertion step S12), thereby manufacturing the structure 10.

### Fixing Step S2

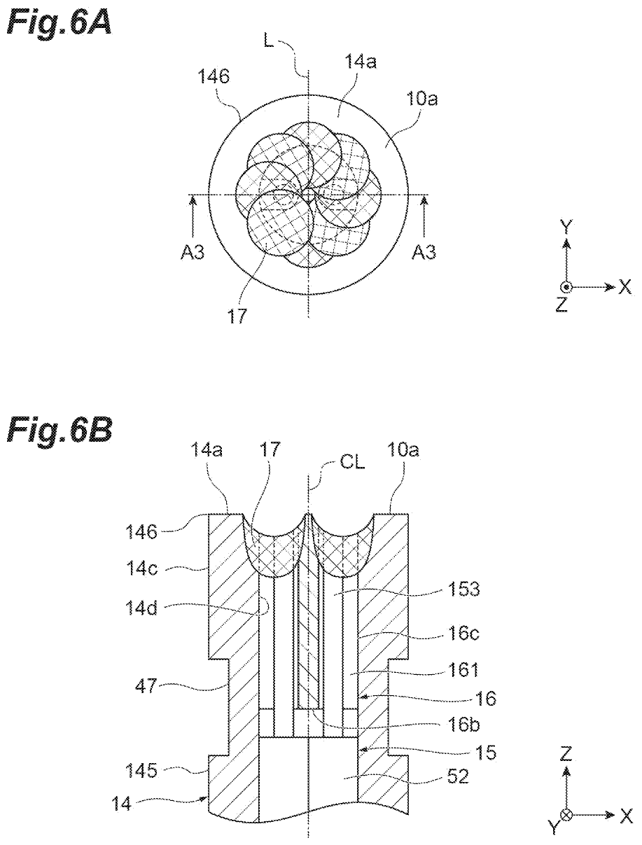

Following the preparation step S1, the fixing step S2 is performed. The fixing step S2 will be described in detail with reference to FIGS. 6A and 6B. FIG. 6A is a plan view for explaining the fixing step S2 shown in FIG. 3. FIG. 6B is a cross-sectional view showing a cross section along the line A3-A3 in FIG. 6A, As shown in FIGS. 6A and 6B, the fixing step S2 is a step of fixing the piece 16 to the housing 14 by first welding on the distal end face 10a. The distal end face 10a includes the first end 14a, the distal end portions 153a of the pair of wires 153, and the front face 16a. By the first welding, the housing 14, the piece 16 and the thermocouple 15 (the pair of wires 153) are joined to each other on the distal end face 10a. For example, a YAG laser is used for the first welding.

The first welding is performed inside the outer edge 146 of the first end 14a in the distal end face 10a. Specifically, the first welding is performed along the boundary between the housing 14 and the piece 16 on the distal end face 10a. Since the boundary has a circular shape centered on the central axis CL, the first welding is performed in a circular shape. A welded portion 17 is formed by the first welding. Specifically, the first end 14a, the pair of wires 153, and the front face 16a on the distal end face 10a are incited and joined to each other to form the welded portion 17. At this time, the distal end portions 153a are melted away by the first welding.

### Fixing Step S3

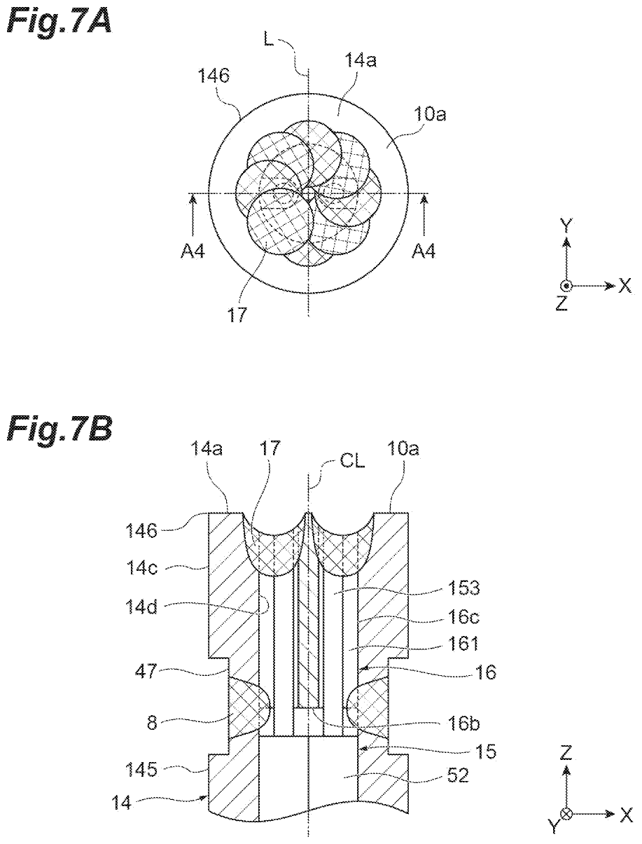

Following the fixing step S2, the fixing step S3 is performed. The fixing step S3 will be described in detail with reference to FIGS. 7A and 7B, FIG. 7A is a plan view for explaining the fixing step S3 shown in FIG. 3. FIG. 7B is a cross-sectional view showing a cross section along the line A4-A4 in FIG. 7A. As shown in FIGS. 7A and 7B, the fixing step S3 is a step of fixing the piece 16 to the housing 14 by second welding on the outer peripheral surface 14c of the housing 14. The second welding is performed in the groove 47 provided on the outer peripheral surface 14c of the housing 14. Therefore, the groove 47 and the bottom portion of the piece 16 are joined together by the second welding. For example, a YAG laser is used for the second welding.

The welded portion 8 is formed by the second welding. Specifically, the groove 47 and the piece 16 are melted and joined to each other to form the welded portion 8. The welded portion 8 may include the pair of wires 153 melted by the second welding. In other words, the welded portion 8 may reach the pair of wires 153.

### Polishing Step S4

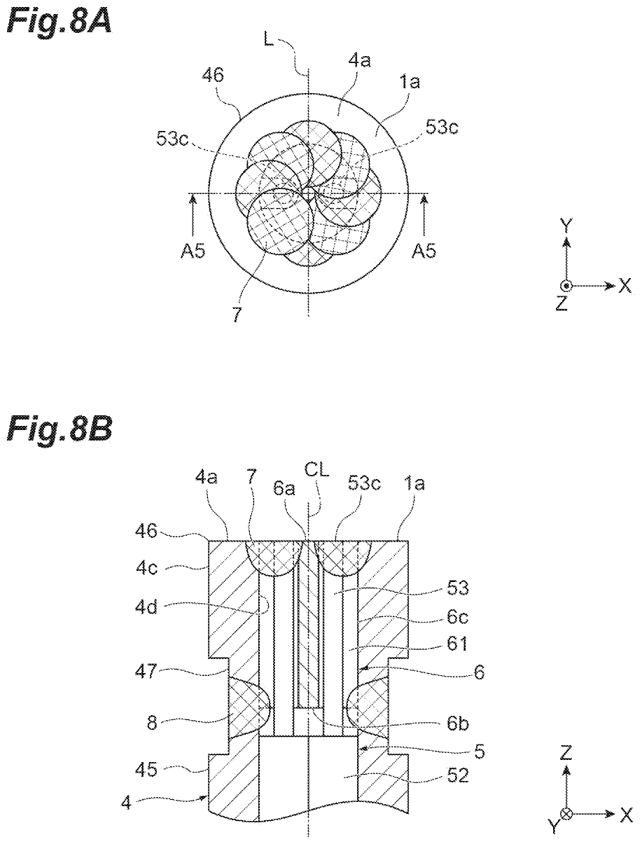

Following the fixing step S3, the polishing step S4 is performed. The polishing step S4 will be described in detail with reference to FIGS. 8A and 8B. FIG. 8A is a plan view for explaining the polishing step S4 shown in FIG. 3. FIG. 8B is a cross-sectional view showing a cross section along the line A5-A5 in FIG. 8A. As shown in FIGS. 8A and 8B, the polishing step S4 is a step of polishing the welded portion 17 and the distal end face 10a. For example, sandpaper is used for polishing.

In the polishing step S4, the welded portion 17 and the distal end face 10a are polished to form the distal. end face 1a. Specifically, the distal end face 1a is formed by polishing the welded portion 17 and the distal end face 10a so as to be flat and expose the pair of wires 153. In other words, the welded portion 17, the housing 14 (first end 14a), the thermocouple 15, and the piece 16 (front face 16a) are polished to form the welded portion 7, the housing 4 (first end 4a), the thermocouple 5, and the piece 6 (front face 6a), respectively. The distal ends 53c of the thermocouple 5 are exposed on the distal end face 1a.

Thus, the measuring device 1 is manufactured.

As described above, in the manufacturing method M1 and the measuring device 1, the thermocouple 15 is accommodated between the pair of grooves 161 provided on the side face 16c of the piece 16 and the inner surface 14d of the housing 14 by inserting the piece 16 into the housing 14. That is, two holes are formed by the inner surface 14d of the housing 14 and the grooves 161, and the thermocouple 15 is already accommodated in the holes at the time when the holes are formed. This eliminates the need to pass the thermocouple 15 through holes having inner diameters equivalent to the outer diameter of the wire 153 of the thermocouple 15. As a result, manufacturing of the measuring device 1 can be facilitated.

In the preparation step S1, the thermocouple 15 is inserted into the housing 14, and then the piece 16 is inserted into the housing 14, whereby the thermocouple 15 is accommodated between the pair of grooves 161 and the inner surface 14d of the housing 14. According to the preparation step S1, the pair of grooves 161 are aligned with the thermocouple 15 in the width direction of the groove 161, and then the piece 16 is inserted into the housing 14, whereby the thermocouple 15 is fitted into the grooves 161 along the grooves 161 as the piece 16 is inserted. Two holes are formed by the inner surface 14d of the housing 14 and the grooves 161, and the thermocouple 15 is already accommodated in the holes at the time when the holes are formed. For example, in order to insert the thermocouple 15 into holes having inner diameters equivalent to the outer diameter of the wire 153 of the thermocouple 15, it is necessary to align the thermocouple 15 with the holes in two axes. On the other hand, in the preparation step S1, the positioning in two axes (the width direction of the groove 161 and the length direction of the groove 161) is individually performed. Therefore, compared with the case where the thermocouple 15 is inserted into the holes provided in the housing, the manufacturing of the measuring device 1 can be facilitated.

Since the distal end face 1a forms a part of the mold, the resin molded article has a shape corresponding to the shape of the distal end face 1a. Therefore, if deformation such as sagging occurs on the distal end face 1a, there is a possibility that the shape of the resin molded article does not conform to the design. Therefore, flatness is required for the distal end face 1a. On the other hand, in the fixing step S2, the first welding is performed inside the outer edge 146 of the first end 14a. This makes it possible to prevent deformation such as sagging of the outer edge 146 due to welding. As a result, the flatness of the distal end face la formed by polishing can be improved.

In the fixing step S2, the first welding is performed along the boundary between the housing 14 and the piece 16 on the distal end face 10a. Thus, since the boundary between the housing 14 and the piece 16 on the distal end face 10a is welded without any gap, the bonding strength between the housing 14 and the piece 16 is improved. As a result, the withstand voltage performance of the measuring device 1 is improved.

in the fixing step S3, the piece 16 is fixed to the housing 14 by the second welding on the outer peripheral surface 14c of the housing 14. Therefore, since the piece 16 is fixed to the housing 14 not only on the distal end face 10a but also on the outer peripheral surface 14c, the bonding strength between the housing 14 and the piece 16 is further improved. As a result, the withstand voltage performance of the measuring device 1 is further improved.

For example, when the measuring device 1 is used in a state where the measuring device 1 is inserted into a hole provided in a metal mold, there is a risk that the measuring device 1 in which the outer peripheral surface 4c of the housing 4 is raised cannot be inserted into the hole, On the other hand, the second welding is performed in the groove 47 provided on the outer peripheral surface 14c of the housing 14. Thus, even if deformation such as bulging occurs in the housing 14 due to the second welding, the deformation occurs in the groove 47. This makes it possible to reduce the possibility that the deformed portion protrudes from the outer peripheral surface 4c. Therefore, it is possible to reduce the possibility that the measuring device 1 cannot be inserted into the hole provided in the mold.

In the polishing step S4, the welded portion 17 and the distal end face 10a are polished so that the distal end of the thermocouple 15 (wire 153) is exposed. Therefore, when the measuring device 1 is used, the time required for heat to reach the pair of wires 53 is shortened. This makes it possible to improve the response of the measuring device 1.

In the measuring device 1, the pair of wires 53 are accommodated in the pair of grooves 61. This stabilizes the positions of the pair of wires 53 in the housing 4. A plurality of measuring devices 1 manufactured by the manufacturing method M1 include pieces 6 having substantially the same volume. Therefore, since the heat capacity of the distal end portion 45 is stabilized, the time during which heat reaches the pair of wires 53 becomes substantially constant. As a result, it is possible to reduce an individual difference in response of the measuring device 1.

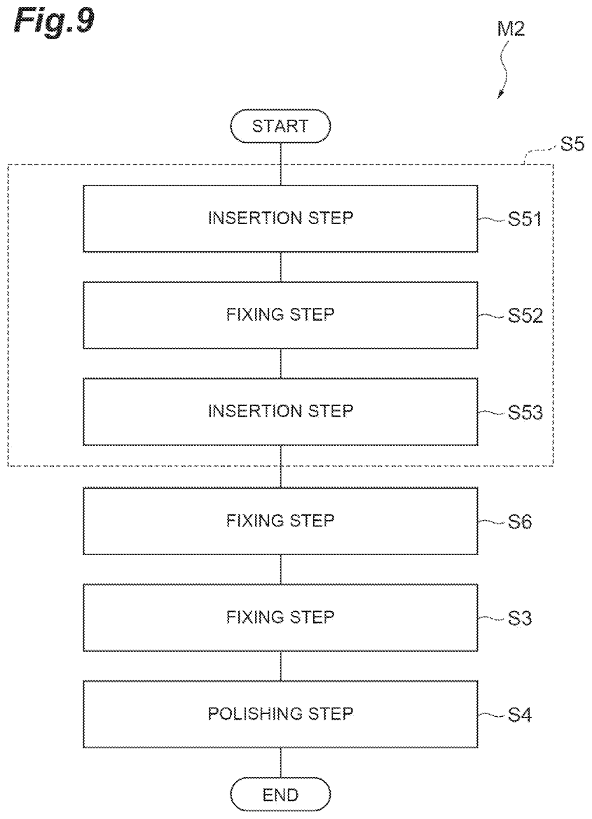

A method for manufacturing the measuring device 1 according to another embodiment will be described with reference to FIG. 9. FIG. 9 is a flowchart showing an example of a method for manufacturing the measuring device I according to another embodiment. As shown in FIG. 9, a. manufacturing method M2 is mainly different from the manufacturing method M1 in that the manufacturing method M2 includes a preparation step S5 and a fixing step S6 instead of the preparation step S1 and the fixing step S2

### Preparation Step S5

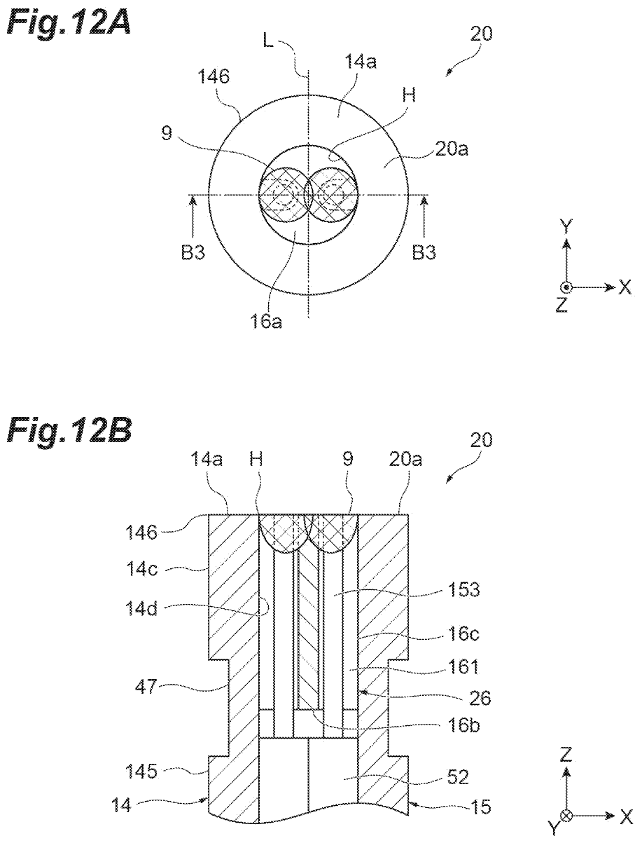

First, the preparation step S5 is performed. The preparation step S5 is a step of preparing a structure 20. The structure 20 is mainly different from the structure 10 in that the structure 20 includes a distal end face 20a instead of the distal end face 10a and further includes a welded portion 9 (see FIG. 12B). The welded portion 9 is provided so as to cover a region where the grooves 161 are formed on the front face 16a, of the piece 16. The piece 16 and the thermocouple 15 (wire 153) are fixed to each other on the front face 16a by the welded portion 9. The distal end face 20a is a face including the first end 14a. In the structure 20, each wire 153 does not have the distal end portion 153a. In the preparation step S5, by inserting the piece 16 into the housing 14, the thermocouple 15 is accommodated between the pair of grooves 161 and the inner surface 14d of the housing 14. The preparation step S5 includes an insertion step S51, a fixing step S52, and an insertion step S53.

### Insertion Step S51

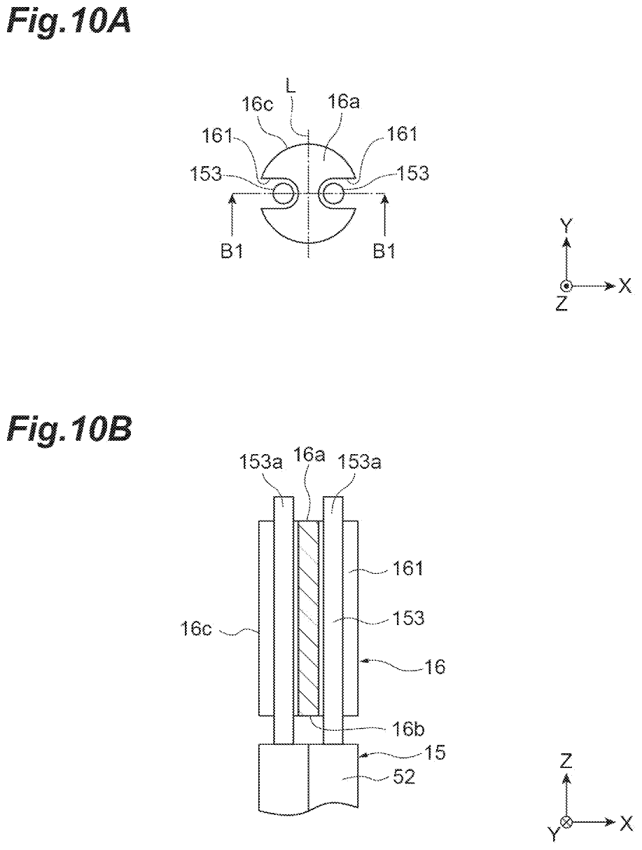

The insertion step S51 will be described in detail with reference to FIGS. 10A and 10B. FIG. 10A is a plan view for explaining the insertion step S51 shown in FIG. 9. FIG. 10B is a cross-sectional view showing a cross section along the line B1-B1 in FIG. 10A. As shown in FIGS. 10A and 10B, the inserting step S51 is a step of inserting the thermocouple 15 into the piece 16. In the insertion step S51, for example, the distal end portion of the thermocouple 15 is inserted into the pair of grooves 161 from the back face 16b or the side face 16c. At this time, the thermocouple 15 is inserted into the piece 16 so that each distal end portion 153a of the pair of wires 153 projects from the front face 16a to the outside of the piece 16.

### Fixing Step S52

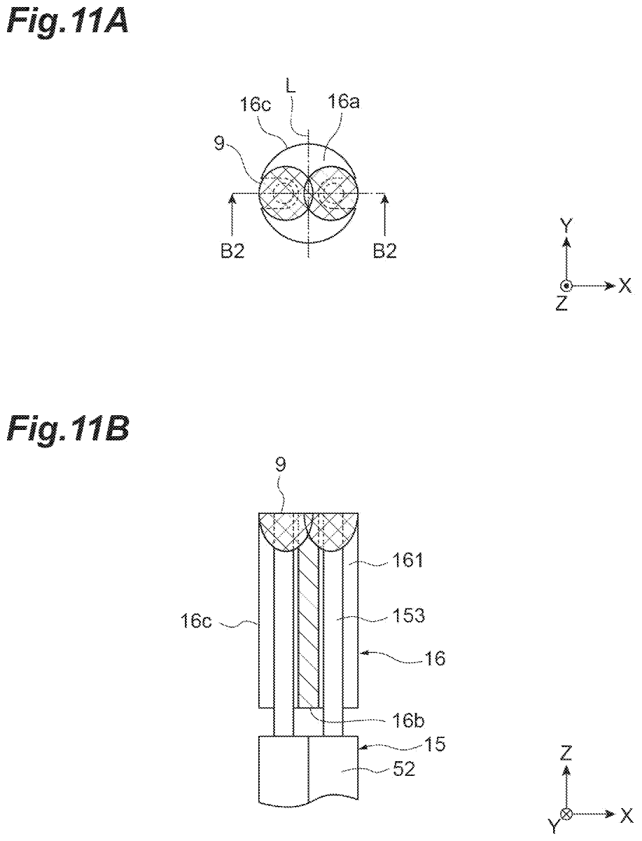

Following the insertion step S51, the fixing step S52 is performed. The fixing step S52 will he described in detail with reference to FIGS. 11A and 11B. FIG. 11A is a plan view for explaining the fixing step S52 shown in FIG, 9. FIG. 11B is a cross-sectional view showing a cross section along the line B2-B2 FIG. 11A. As shown in FIGS. 11A and 11B, the fixing step S52 is a step of fixing the thermocouple 15 to the piece 16 by auxiliary welding on the front face 16a.

The auxiliary welding is performed at a portion where the pair of grooves 161 are formed on the front face 16a. By the auxiliary welding, the piece 16 and the thermocouple 15 are joined to each other on the front face 16a. For example, a YAG laser is used for the auxiliary welding. The welded portion 9 is formed by the auxiliary welding. Specifically, the pair of wires 153 on the front face 16a and the front face 16a are melted and joined to each other to form the welded portion 9. At this time, the distal end portions 153a are melted away by the auxiliary welding.

### Insertion Step S53

Following the fixing step S52, the inserting step S53 is performed. The insertion step S53 will be described in detail with reference to FIGS. 12A and 12B. FIG. 12A is a plan view for explaining the insertion step S53 shown in FIG. 9. FIG. 12B is a cross-sectional. view showing a cross section along the line B3-B3 in FIG. 12A. As shown in FIGS, 12A and 12B, the insertion step S53 is a step of inserting the piece 16 and the thermocouple 15, which are joined to each other, into the housing 14.

In the insertion step S53, for example, the piece 16 and the thermocouple 15, which are joined to each other, are inserted into the housing 14 from the second end 4b of the housing 14. At this time, the thermocouple 15 is accommodated in the pair of grooves 161. The piece 16 is then inserted into the housing 14 until the front face 16a is flush with the first end 14a. As a result, the thermocouple 15 (the pair of wires 153) is accommodated between the pair of grooves 161 and the inner surface 14d of the housing 14. At this time, the front face 16a is exposed from the first end 14a. The piece 16 may be inserted into the housing 14 so that the front face 16a is positioned slightly inside the housing 14 than the first end 14a. In other words, the piece 16 may be inserted into the housing 14 so that the distal ends of the pair of wires 153 do not protrude outside the housing 14 from the first end 14a.

As described above, in the preparation step S5, the thermocouple 15 is inserted into the piece 16 (insertion step S51), and fixed to the piece 16 (fixing step S52), Thereafter, the piece 16 and the thermocouple 15, which are joined to each other, are inserted into the housing 14, so that the thermocouple 15 is accommodated between the pair of grooves 161 and the inner surface 14d of the housing 14 (insertion step S53), thereby manufacturing the structure 20.

### Fixing Step S6

Following the preparation step SS, the fixing step S6 is performed. The fixing step S6 is a step of fixing the piece 16 to the housing 14 by the first welding on the distal end face 20a, similarly to the fixing step S2. The distal end face 20a includes the first end 14a, the front face 16a and the welded portion 9. By the first welding, the housing 14 and the piece 16 are joined to each other on the distal end face 20a. Since the piece 16 and the thermocouple 15 are already joined to each other on the front face 16a, the housing 14, the piece 16 and the thermocouple 15 (the pair of wires 153) are joined to each other on the distal end face 20a, after the first welding is performed.

The first welding is performed inside the outer edge 146 of the first end 14a in the distal end face 20a. Specifically, the first welding is performed along the boundary between the housing 14 and the piece 16 on the distal end face 20a. Since the boundary has a circular shape centered on the central axis CL, the first welding is performed in a circular shape. The welded portion 17 is formed by the first welding. Specifically, the first end 14a, the front face 16a, and the welded portion 9 on the distal end face 20a are melted and joined to each other to form the welded portion 17.

Since the fixing step S3 and the polishing step S4 are the same as the manufacturing method M1, the description thereof is omitted. Thus, the measuring device 1 is manufactured.

In the preparation step S5, in a state where the thermocouple 15 is accommodated in the pair of grooves 161, the thermocouple 15 is fixed to the piece 16 by the auxiliary welding on the front face 16a of the piece 16, and then the piece 16 and the thermocouple 15 are inserted into the housing 14 so that the front face 16a is exposed from the first end 14a, whereby the thermocouple 15 is accommodated between the pair of grooves 161 and the inner surface 14d of the housing 14. According to the preparation step S5, the thermocouple 15 is aligned with the pair of grooves 161 in the width direction of the groove 161, and then the thermocouple is aligned with the piece 16 along the grooves 161. Therefore, since the positioning in the two axes (the width direction of the groove 161 and the length direction of the groove 161) is individually performed, the manufacturing of the measuring device 1 can be facilitated as compared with the case where the thermocouple 15 is inserted into the holes provided in the housing.

Embodiments of the present disclosure have been described in detail above. However, the method for manufacturing a measuring device and the measuring device according to the present disclosure are not limited to the above-described embodiments, The method for manufacturing a measuring device and the measuring device according to the present disclosure can be variously modified without departing from the spirit and scope thereof.

For example, the fixing step S3 may be omitted as long as sufficient bonding strength between the housing 14 and the piece 16 is obtained in the fixing step S2 or S6.

In the fixing step S3, the second welding may be performed on the outer peripheral surface 14c other than the groove 47 of the housing 14. In this case, the groove 47 do not have to he provided on the outer peripheral surface 14c of the housing 14.

### Additional Statements

### Clause 1

A method for manufacturing a measuring device, the method comprising:
a step of preparing a structure, the structure including:
   a housing having a cylindrical shape in which a first end and a second end in one direction are open;
   a thermocouple extending in the one direction in the housing; and
   a piece having a columnar shape, the piece provided in the housing, the piece exposed from the first end, the piece configured to hold the thermocouple;
a step of fixing the piece to the housing by first welding on a distal end face of the structure, the distal end face including the first end; and
a step of polishing a welded portion formed by the first welding and the distal end face,
wherein the piece has a side face facing an inner surface of the housing,
wherein a pair of grooves penetrating through the piece the one direction are provided on the side face, and.
wherein in the step of preparing the structure, the thermocouple is accommodated between the pair of grooves and the inner surface of the housing by inserting the piece into the housing.

### Clause 2

The method for manufacturing a measuring device according to clause 1, wherein in the step of preparing the structure, the thermocouple is accommodated between the pair of grooves and the inner surface of the housing by inserting the piece into the housing after inserting the thermocouple into the housing.

### Clause 3

The method for manufacturing a measuring device according to clause 1, wherein in the step of preparing the structure, the thermocouple is accommodated between the pair of grooves and the inner surface of the housing by inserting the piece and the thermocouple into the housing so that a front face of the piece is exposed from the first end after fixing the thermocouple to the piece by auxiliary welding on the front face in a state in which the thermocouple is accommodated in the pair of grooves.

### Clause 4

The method for manufacturing a measuring device according to any one of clauses 1 to 3, wherein the first welding is performed inside an outer edge of the first end.

### Clause 5

The method for manufacturing a measuring device according to clause 4, wherein the first welding is performed along a boundary between the housing and the piece on the distal end face.

### Clause 6

The method for manufacturing a measuring device according to any one of clauses 1 to 5, further comprising:
a step of fixing the piece to the housing second welding on an outer peripheral surface of the housing.

### Clause 7

The method for manufacturing a measuring device according to clause 6, wherein a groove is provided on the outer peripheral surface of the housing, and
wherein the second welding is performed in the groove.

### Clause 8

The method for manufacturing a measuring device according to any one of clauses 1 to 7, wherein in the step of polishing the welded portion and the distal end face, the welded portion and the distal end face are polished so that distal ends of the thermocouple are exposed.

What is claimed is:

1. A method for manufacturing a measuring device, the method. comprising:
a step of preparing a structure, the structure including:
a housing having a cylindrical shape in which a first end and a second end in one direction are open;
a thermocouple extending in the one direction in the housing; and
a piece having a columnar shape, the piece provided in the housing, the piece exposed from the first end, the piece configured to hold the thermocouple;
a step of fixing the piece to the housing by first welding on a distal end face of the structure, the distal end face including the first end; and
a step of polishing a welded portion formed by the first welding and the distal end face,
wherein the piece has a side face facing an inner surface of the housing,
wherein a pair of grooves penetrating through the piece in the one direction are provided on the side face, and wherein in the step of preparing the structure, the thermocouple is accommodated between the pair of grooves and the inner surface of the housing by inserting the piece into the housing.

2. The method for manufacturing a measuring device according to claim 1, wherein in the step of preparing the structure, the thermocouple is accommodated between the pair of grooves and the inner surface of the housing by inserting the piece into the housing after inserting the thermocouple into the housing.

3. The method for manufacturing a measuring device according to claim 1, wherein in the step of preparing the structure, the thermocouple is accommodated between the pair of grooves and the inner surface of the housing by inserting the piece and the thermocouple into the housing so that a front face of the piece is exposed from the first end. after fixing the thermocouple to the piece by auxiliary welding on the front face in a state in which the thermocouple is accommodated in the pair of grooves.

4. The method for manufacturing a measuring device according to claim 1, wherein the first welding is performed inside an outer edge of the first end.

5. The method for manufacturing a measuring device according to claim 4, wherein the first welding is performed along a boundary between the housing and the piece on the distal end face.

6. The method for manufacturing a measuring device according to claim 1, further comprising:
a step of fixing the piece to the housing by second welding on an outer peripheral. surface of the housing.

7. The method for manufacturing a measuring device according to claim 6, wherein a groove is provided on the outer peripheral surface of the housing, and
wherein the second welding is performed in the groove.

8. The method for manufacturing a measuring device according to claim 1, wherein in the step of polishing the welded portion and the distal end face, the welded portion and the distal end face are polished so that distal ends of the thermocouple are exposed.

9. A measuring device comprising:
a housing having a first end and a second end in one direction, the housing having a cylindrical shape in which the first end and the second end are open;
a thermocouple extending in the one direction in the housing; and
a piece having a columnar shape, provided in the housing, exposed from the first end and configured to hold the thermocouple,
wherein the piece has a side face facing an inner surface of the housing and a distal end face exposed from the first end,
wherein a pair of grooves penetrating through the piece in the one direction are provided on the side face, and
wherein the thermocouple is accommodated in the pair of grooves and extends to the distal end face.
